(19) United States
(12) Patent Application Publication
(10) Pub. No.: US 2018/0358502 A1
(43) Pub. Date: Dec. 13, 2018

(54) SENSOR SUBSTRATE AND SENSOR DEVICE

(71) Applicant: KYOCERA Corporation, Kyoto-shi, Kyoto (JP)

(72) Inventors: Shigetoshi INUYAMA, Kirishima-shi (JP); Yoshimasa SUGIMOTO, Kirishima-shi (JP)

(73) Assignee: KYOCERA Corporation, Kyoto-shi, Kyoto (JP)

(21) Appl. No.: 15/767,700

(22) PCT Filed: Dec. 2, 2016
(86) PCT No.: PCT/JP2016/085934

§ 371 Date: Apr. 12, 2018

(30) Foreign Application Priority Data
Dec. 10, 2015 (JP) 2015-241243

(51) Int. Cl. H01L 31/173

(52) U.S. Cl. CPC H01L 31/173

(57) ABSTRACT

A sensor substrate includes a substrate comprising an upper surface including a first mounting area on which a light-emitting element is mounted, and a lower surface including a second mounting area on which a light-receiving element is mounted. The substrate is further provided with a through hole therethrough extending from a portion of the upper surface which portion is adjacent to the first mounting area, to the second mounting area of the lower surface. An inner surface of the through hole is provided with at least one protrusion (a first protrusion and a second protrusion) extending inwardly within the through hole.

### TECHNICAL FIELD

The present invention relates to a sensor substrate comprising a mounting area for mounting a sensor element, and to a sensor device.

### BACKGROUND ART

In an electronic apparatus such as a mobile phone or a tablet PC (Personal Computer), an optical sensor device comprising a light-emitting element and a light-receiving element has been used. The sensor device is constructed by arranging a light-emitting element and a light-receiving element in juxtaposition on an upper surface of a substrate. Light is emitted outwardly from the light-emitting element, and, the light reflected by a target object such as a user of the electronic apparatus is sensed by the light-receiving element. In response to the sensing of the light, for example, the approach of the target object is sensed.

From the viewpoint of downsizing such a sensor device in plan view, it has been considered advisable to arrange the light-emitting element and the light-receiving element separately in a vertical direction of the substrate. In this case, the light reflected by the target object (reflected light) passing through a through hole provided in the substrate is received by the light-receiving element (for example, refer to Patent Literature 1).

### CITATION LIST

### Patent Literature

Patent Literature 1: U.S. Unexamined Patent Application Publication No. 2013/0341650

Patent Literature 2: Japanese Unexamined Patent Publication JP-A 2011-49473

SUMMARY OF INVENTION

The inventors of the invention have accomplished the invention with their attentions focused on the fact that reflected light from a target object and the other light than the reflected light, which is regarded as undesired light, enter a through hole at different angles of incidence.

A sensor substrate according to one aspect of the invention comprises a substrate comprising an upper surface including a first mounting area for mounting a light-emitting element, and a lower surface including a second mounting area for mounting a light-receiving element. The substrate is further provided with a through hole therethrough extending from a portion of the upper surface which portion is adjacent to the first mounting area, to the second mounting area of the lower surface. An inner surface of the through hole is provided with at least one protrusion extending inwardly within the through hole.

A sensor device according to one aspect of the invention, comprises: the sensor substrate mentioned above; a light-emitting element mounted on the first mounting area; a light-transmitting sealing material which covers the light-emitting element; and a light-receiving element having a light-receiving portion. The light-receiving element is mounted on the second mounting area so that the light-receiving portion faces an opening of the through hole.

### BRIEF DESCRIPTION OF DRAWINGS

FIG. 1A is a plan view showing a sensor substrate and a sensor device in accordance with an embodiment of the invention, and FIG. 1B is a sectional view taken along the line A-A shown in FIG. 1A;

FIG. 2 is a sectional view showing the sensor substrate and the sensor device in accordance with an embodiment of the invention, and also a portion of an electronic apparatus;

FIGS. 3A and 3B are each a sectional view showing the principal part of a modified example of the sensor substrate and the sensor device in accordance with the embodiment of the invention;

FIG. 4 is a sectional view showing the principal part of another modified example of the sensor substrate and the sensor device in accordance with the embodiment of the invention;

FIG. 5 is a plan view showing another modified example of the sensor device in accordance with the embodiment of the invention;

FIGS. 6A and 6B are each a sectional view showing the principal part of another modified example of the sensor substrate and the sensor device in accordance with the embodiment of the invention; and

FIG. 7 is a plan view showing still another modified of the sensor substrate and the sensor device in accordance with the embodiment of the invention.

### DESCRIPTION OF EMBODIMENTS

Now reference to the accompanying drawings, a sensor substrate in accordance with an embodiment of the invention will be described below. In what follows, for convenience in illustrating the invention, vertically opposite sides of the construction will be designated as the upper and lower sides, it being understood that such a designation is not intended to be limiting of the orientation of the sensor substrate and a sensor device 20 in actual use. Moreover, a light-transmitting part is not hatched in the drawings to be hereafter referred to, even in the sectional view.

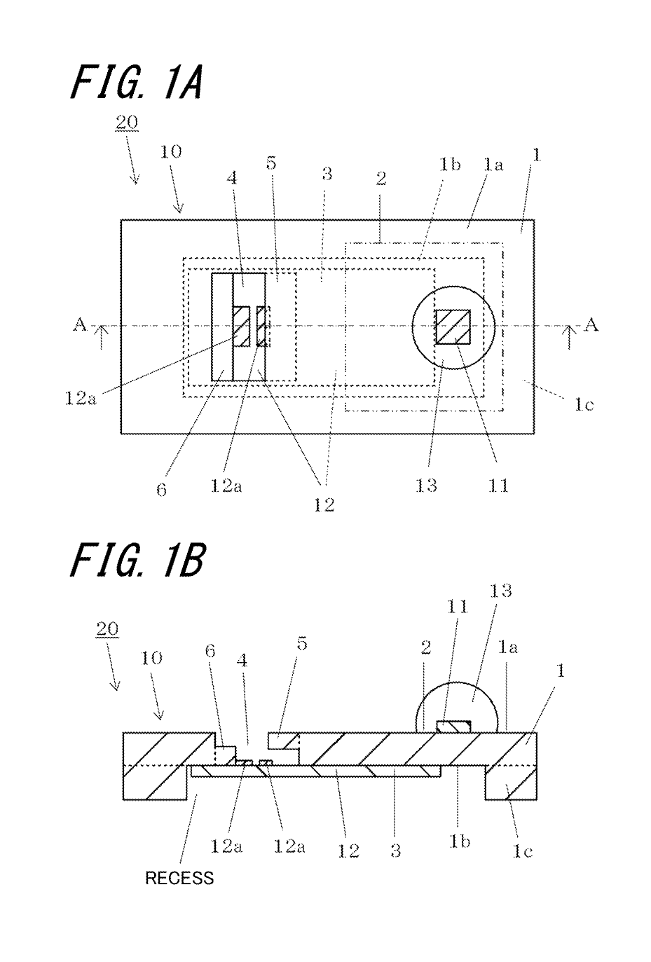

FIG. 1A is a plan view showing a sensor substrate 10 and a sensor device 20 in accordance with an embodiment of the invention, and FIG. 1B is a sectional view taken along the line A-A shown in FIG. 1A.

The sensor substrate 10 of the present embodiment comprises a substrate 1 shaped in a quadrangular plate having an upper surface 1a and a lower surface 1b which are shaped in, for example, a quadrangular form. The upper surface 1a of the substrate 1 is provided with a first mounting area 2 for mounting a light-emitting element 11. The lower surface 1b of the substrate 1 is provided with a second mounting area 3 for mounting a light-receiving element 12.

The sensor device 20 of the present embodiment is constructed by mounting the light-emitting element 11 on the first mounting area 2, and mounting the light-receiving element on the second mounting area 3. The sensor device 20 thus constructed is installed in an electronic apparatus. For example, the installed sensor device 20 is used as an optical proximity sensor device 20. Examples of the electronic apparatus include a mobile phone such as a smartphone, a PC such as a tablet PC, and an automotive sensor apparatus. Each such sensor apparatus is one of various types of an electronic apparatus having optical detection capability.

The substrate 1 is provided with a through hole 4 therethrough extending across the upper surface 1a and the lower surface 1b thereof. The upper opening of the through hole 4 is adjacent to the first mounting area 2 of the upper surface 1a of the substrate 1. A distance between the through hole 4 and the first mounting area 2 is set at about 1.2 to 1.5 mm, for example. In the example shown in FIGs. 1A and 1B, a portion of the upper surface 1a on the right side from the center of the upper surface 1a of the substrate 1, as indicated in outline by the chain double-dashed line, is defined as the first mounting area 2.

The first mounting area 2 may be provided with a wiring conductor (not shown) which is electrically connected to the light-emitting element 11. For example, the wiring conductor may be formed so as to extend from the first mounting area 2 to the interior of the substrate 1, and from there to the outer surface of the sensor substrate 10. The outer surface of the sensor substrate 10 corresponds to, for example, the lower surface 1b of the substrate 1, or the lower surface of a frame portion 1c which will hereafter be described, etc. Via the wiring conductor, electrical connection is established between the light-emitting element 11 and an external electric circuit (not shown). Examples of the external electric circuit include an electronic circuit provided in a circuit board such as a motherboard incorporated in an electronic apparatus.

Moreover, the second mounting area 3 may also be provided with a wiring conductor similar to that as above described. The wiring conductor may be formed so as to extend from the second mounting area 3 to the outer surface of the substrate 1. Just as is the case with the light-emitting element 11, the wiring conductor may be electrically connected to the light-receiving element 12 for establishing electrical connection between the light-receiving element 12 and an external electric circuit.

The lower opening of the through hole 4 is positioned within the second mounting area 3. For example, the second mounting area 3 corresponds to the central region of the lower surface 1b of the substrate 1. In the example shown in FIGs. 1A and 1B, a frame portion 1c is laminated on the outer periphery of the lower surface 1b of the substrate 1. The second mounting area 3 is defined by the lower surface 1b of the substrate 1 left exposed inside the frame portion 1c.

The substrate 1 in the sensor substrate 10 of the present embodiment may be regarded as a type which has a recess (so-called cavity) for receiving therein the light-receiving element 12 on a lower surface side thereof. That is, in the substrate 1 as seen in transparent plan view, the through hole 4 is provided so as to be adjacent to the first mounting area 2, as well as to lie within the recess. In other words, the through hole 4 is located at a position where incidence of light emitted from the light-emitting element 11 mounted at a certain distance from the through hole 4 (reflected light) is easy. In addition, the through hole 4 is located at a position where the reflected light is easily passed toward the light-receiving element 12 mounted immediately below the through hole 4.

The through hole 4 serves to enable transmission and reception of light between the first mounting area 2 and the second mounting area 3. By the transmission and reception of light, detection of a target object (not shown) approaching the electronic apparatus is performed.

More specifically, the light emitted outwardly from the light-emitting element 11 mounted on the first mounting area 2 is reflected by the target object existing outside the sensor device 20, and the light (reflected light) returns to the sensor device 20. The reflected light passes through the through hole 4, and is sensed by the light-receiving element 12 mounted on the second mounting area 3. By the sensing of the reflected light, for example, the existence or approach of the target object is detected.

When the electronic apparatus in which the sensor device is installed is, for example, a mobile phone such as a smartphone, then the target object is the face of a mobile phone user. In the sensor device 20 installed as a proximity sensor device in a smartphone which is the electronic apparatus, light is emitted outwardly (upwardly) from the light-emitting element 11. When the target object, viz., user's face, approaches the electronic apparatus, the light is reflected by the target object, and then returns to the sensor device 20, and the amount of incident light (luminous flux) entering the through hole 4 is increased. The increase of the light amount is detected by the light-receiving element 12, and the approach of the target object, for example, user's move to start smartphone operation, is detected.

For example, a gallium-arsenide (Ga—As) light-emitting (infrared-emitting) diode may be used as the light-emitting element 11. On the other hand, for example, a photodiode (infrared photodiode) may be used as the light-receiving element 12. Light to be received by or emitted from each element may be infrared rays. The light-receiving element 12 is composed of a main body (no reference numeral) composed of a semiconductor substrate such for example as a silicon substrate, and a light-receiving portion 12a located on part of the upper surface of the main body. The main body of the light-receiving element 12 may be additionally provided with a logic circuit or the like for processing information about light reception. In the sensor device 20, with the placement of an illuminance sensor-specific detecting circuit on a light-receiving element 12—bearing side thereof, in addition to the described proximity sensor function, an illuminance sensor function can also be attained.

The light-receiving element 12 needs to be configured to receive reflected light which passes through the through hole 4 as described above. Thus, the light-receiving element 12 is mounted so that a light-receiving portion 12a thereof faces the lower-end opening of the through hole 4.

Examples of the material for forming the substrate 1 include a ceramic material, and a composite material containing an organic resin material and a ceramic material. Examples of the ceramic material include ceramic sintered body materials such as an aluminum oxide sintered body, a glass ceramic sintered body, an aluminum nitride sintered body, a silicon nitride sintered body, and a mullite sintered body. Examples of the organic resin material include epoxy resin, polyimide resin, polyamide-imide resin, and phenol resin.

For example, in the case where the substrate 1 is formed of an aluminum oxide sintered body, the substrate 1 can be produced in the following manner. To begin with, raw material powder such as aluminum oxide and silicon oxide is kneaded with suitable organic binder and organic solvent to prepare a slurry. The slurry is then shaped into sheet form by the doctor blade method or lip coater method to prepare a ceramic green sheet. After that, the ceramic green sheet is cut into a plurality of sheets each having predetermined shape and dimensions. The plurality of sheets are laminated on top of each other into a laminated body, and, the laminated body is fired. The substrate 1 can be produced by the procedure mentioned above.

The frame portion 1c may be formed of a material similar to that used for the substrate 1 (body portion in flat-plate form) by a method similar to that adopted for the formation of the substrate 1. In this case, the ceramic green sheet is punched into a frame-like sheet. The frame-like sheet is laminated on the lower side of the above-described laminated body which becomes the substrate 1, and, the sheet and the laminated body are co-fired. In this way, the substrate having the frame portion 1c can be integrally formed.

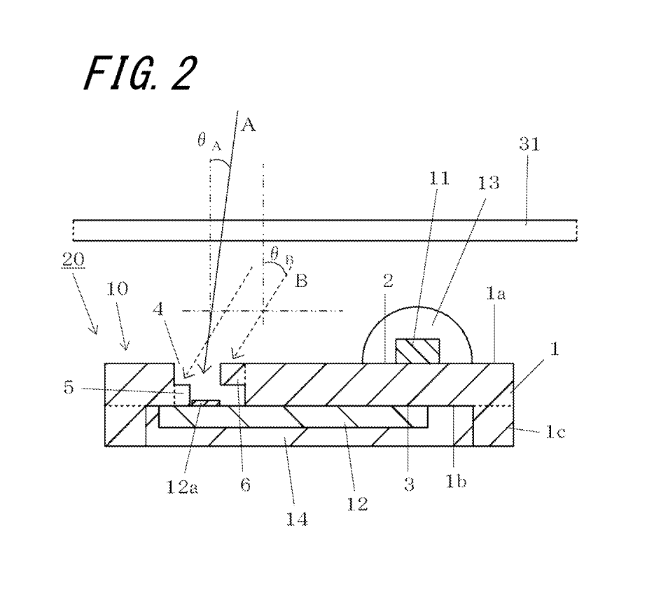

FIG. 2 is a sectional view showing the sensor substrate 10 and the sensor device 20 of the present embodiment, and also a part 31 of the electronic apparatus. In FIG. 2, such constituent components as are common to those shown in FIGs. 1A and 1B are identified with the same reference symbols. A part 31 of the electronic apparatus is, for example, a display panel of a mobile phone. The panel is a plate-like member formed of a light-transmitting material such as glass. The panel is part of a plurality of structural components constituting a housing of the electronic apparatus. In the following description, the part 31 of the electronic apparatus may also be referred to as “glass plate 31”.

The inner surface of the through hole 4 is provided with at least one protrusion extending inwardly within the through hole 4. In this embodiment, as will hereafter be described, a plurality of protrusions (a first protrusion 5 and a second protrusion 6) are arranged on the inner surface of the through hole 4. For example, as shown in FIG. 2, undesired light (light beam B) reflected by, for example, the glass plate 31 which lies at a shorter distance from the light-emitting element 11 than a distance from the target object enters the through hole 4 at an angle of incidence θ_{B} which is greater than an angle of incidence θ_{A} at which the reflected light (light beam A) from the target object enters the through hole 4. Note that the angles of incidence θ_{A} and θ_{B} each correspond to an angle of inclination with respect to the longitudinal direction of the through hole 4 that light beams enter. For example, when light beams enter the through hole 4 along the longitudinal direction of the through hole 4, or equivalently, light beams enter the through hole 4 perpendicularly with respect to the opening of the through hole 4, the angle of incidence is 0°.

In the sensor substrate 10 of the embodiment, undesired light having a relatively large angle of incidence, or equivalently, undesired light which enters the through hole 4 at a lower angle, is effectively blocked by the protrusion lying within the through hole 4. Thus, it is possible to provide the sensor substrate 10 which facilitates manufacture of the sensor device 20 in which the likelihood of undesired light reception by the light-receiving element 12 is effectively diminished.

Moreover, the sensor device 20 of the embodiment comprises the sensor substrate 10 having the above-described structure. Thus, it is possible to provide the sensor device 20 in which the likelihood of undesired light reception by the light-receiving element 12 is effectively diminished.

In the sensor substrate 10 and the sensor device 20 having the above-described structure, the through hole 4 has a quadrangular shape such as a rectangular shape in plan view. The opening at the upper end of the through hole 4 is slightly greater in size than at least the light-receiving portion 12a. For example, each side of the opening of the through hole 4 has a dimension larger than each side of the light-receiving portion 12a by about 100 to 300 μm in plan view.

Moreover, in the sensor substrate 10 and the sensor device 20 having the above-described structure, the dimensions of the first protrusion 5 and the second protrusion 6 (the extending length of each protrusion within the through hole 4) are suitably set to the extent that would permit easy passage of the reflected light A through the through hole 4. For example, the dimensions of the first protrusion 5 and the second protrusion 6 in plan view are set to the extent that would bring most part of the light-receiving portion 12a into view within the through hole 4.

In the sensor substrate 10 and the sensor device 20 of the present embodiment, the through hole 4 of the substrate 1 is formed by, for example, boring a hole through the ceramic green sheet which becomes the substrate 1 (cut sheet having predetermined shape and dimensions) in the thickness direction. Then, a plurality of the cut sheets are laminated together so that their holes are continuous with each other in the vertical direction, thus forming the through hole 4 extending through the substrate 1 in the thickness direction.

Moreover, for example, the first protrusion 5 and the second protrusion 6 lying on the inner surface of such a through hole 4 may be formed of a material similar to that used for the substrate 1 by a method similar to that adopted for the formation of the substrate 1. When laminating together a plurality of the sheets each having a hole for forming the through hole 4 as described above, some sheets may be laminated while being displaced from the others so that the part surrounding the hole protrudes inwardly within the through hole 4 obtained after the lamination of the sheets, and may be co-fired. The protruding parts of the displaced sheets become the first protrusion 5 and the second protrusion 6.

In this case, the ceramic green sheets having parts forming the first protrusion 5 and the second protrusion 6 may contain pigments, such as chromium oxide or molybdenum oxide, which are effective for absorption and interception of light (infrared rays).

Moreover, the first protrusion 5 and the second protrusion 6 may be formed of a ceramic material which differs from that used for the substrate 1, or a material other than a ceramic material such as an organic resin material or a metal material.

In this case, there is used a material which is useful in restraining light from entering the through hole 4 by light (infrared rays) absorption or reflection. Examples of such a material include a resin material with a filler such as a carbon filler added, and a mirror-finished metal material such as molybdenum.

In a case where the substrate 1 is formed of an organic resin material, the through hole 4 having a protrusion of predetermined shape can be formed in the substrate 1 in the following manner, for example. That is, the shaping of the organic resin material is effected with use of a mold capable of forming a protrusion having a predetermined design. The shaping process using the mold permits production of the substrate 1 provided with the through hole 4 having a protrusion such as the first protrusion 5 and the second protrusion 6. Also in this case, for example, a colorant which lends itself to interception of undesired light such as infrared rays may be added to the organic resin material.

Moreover, the light-emitting element 11 may be covered and sealed with a light-transmitting sealing material 13 formed of a light-transmitting resin material such as silicone resin or epoxy resin. This makes it possible to protect the light-emitting element 11 from an external environment, and thereby improve the long-term reliability of the sensor device 20.

The light-receiving element 12 may also be covered and sealed with a sealing material 14 formed of a resin material such as silicone resin or epoxy resin. The sealing material 14 may be a colored material intended to keep undesired light from entering the light-receiving portion 12a from below the sensor device 20.

As in the example shown in FIGS. 1A, 1B and 2, in the case where the inner surface of the through hole 4 is provided with a plurality of protrusions, the protrusions may be located so as to face each other. That is, the plurality of protrusions may include the first protrusion 5 disposed at the upper end of the through hole 4 on the first mounting area 2 side, and the second protrusion 6 disposed at the lower end of the through hole 4 on a side opposite to the first mounting area 2.

When at least one protrusion is provided, it is possible to reduce the possibility of the passage of undesired light having a relatively large angle of incidence through the through hole 4. Moreover, by forming the plurality of protrusions, the possibility of the passage of undesired light through the through hole 4 is reduced.

In this case, since the first protrusion 5 is disposed at the upper end of the through hole 4 on the first mounting area 2 side, the distance from the first mounting area 2 to the opening of the through hole 4 is increased. This leads to an increase in the angle of incidence of undesired light which tries to enter into the opening of the through hole 4 from the first mounting area 2. Hence, the first protrusion 5 serves to reduce the possibility that undesired light will enter the through hole 4. Moreover, the second protrusion 6 is disposed at the lower end of the through hole 4 on the side opposite to the first mounting area 2. This arrangement makes it possible to effectively reduce the possibility that undesired light reflected by a part of the inner surface of the through hole 4 which part lies above the second protrusion 6 (upper side surface) will travel further toward the second mounting area 3. Hence, the second protrusion 6 makes it possible to effectively reduce the possibility of undesired light entry into the second mounting area 3.

Moreover, since the first protrusion 5 and the second protrusion 6 are disposed apart from each other, reflected light having a small angle of incidence is allowed to travel between the first protrusion 5 and the second protrusion 6 so as to reach the second mounting area 2. In this case, as described previously, the dimensions of the first protrusion 5 and the second protrusion 6 are set to the extent that would allow the reflected light A to pass through the through hole 4 so as to be received by the light-receiving portion 12a. By way of example, as described previously, in the case where the through hole 4 has a quadrangular opening having a dimension of about 500 to 1000 μm square, the first protrusion 5 and the second protrusion 6 each have a quadrangular shape having a dimension of about 150 μm by 100 μm.

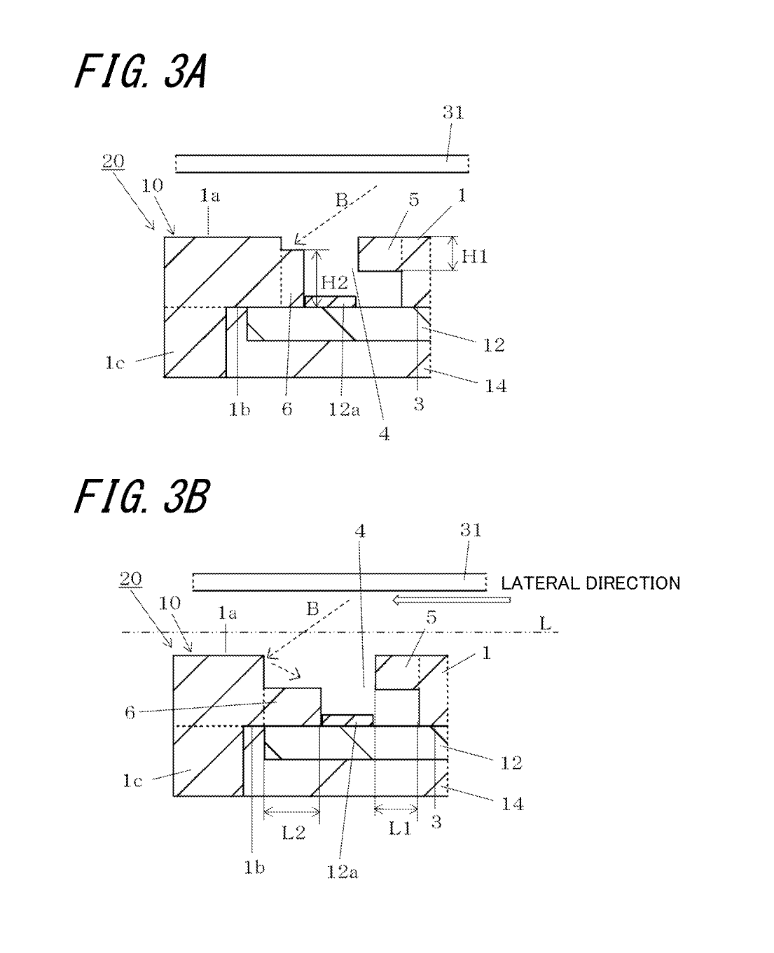

FIGS. 3A and 3B are each a sectional view showing the principal part of a modified example of the sensor substrate 10 and the sensor device 20 in accordance with the embodiment of the invention. In FIGS. 3A and 3B, such constituent components as are common to those shown in FIGS. 1A and 1B are identified with the same reference symbols.

### First and Second Modified Examples

In the example shown in FIG. 3A, a vertical dimension H2 of the second protrusion 6 is greater than a vertical dimension H1 of the first protrusion 5.

In this case, the vertical dimension of a part of the inner surface of the through hole 4 which part lies above the second protrusion 6 (upper side surface) becomes small. That is, the possibility that the undesired light beam B will strike the part of the inner surface of the through hole 4 which part lies above the second protrusion 6 is reduced. Therefore, the amount of undesired light reflected by the upper side surface is reduced. Thus, the amount of undesired light reflected downwardly by the upper side surface for travel to the second mounting area 3 is reduced.

Hence, in the sensor substrate 10 and the sensor device 20 of this modified example, the possibility of undesired light reception by the light-receiving element 12 mounted on the second mounting area 3 is effectively reduced. This makes it possible to provide the sensor device 20 which detects the approach of a target object with high detection accuracy when used as a proximity sensor, for example.

By way of example, a vertical dimension H1 of the first protrusion 5 is about 125 μm, and a vertical dimension H2 of the second protrusion 6 is about 200 μm.

In the example shown in FIG. 3B, a dimension L2 of the second protrusion 6 is greater than a dimension L1 of the first protrusion 5 in a lateral direction along a virtual straight line (half line) L extending from the first mounting area 2 toward the through hole 4.

In this case, undesired light reflected by the upper side surface toward the first mounting area 2 (light beam B) is effectively blocked by the second protrusion 6 having a relatively large dimension in the reflection direction of the light beam B.

Thus, also in the sensor substrate 10 and the sensor device 20 of this modified example, the possibility of undesired light reception by the light-receiving element 12 mounted on the second mounting area 3 is effectively reduced.

By way of example, a lateral dimension L1 of the first protrusion 5 is about 150 μm, and a lateral dimension L2 of the second protrusion 6 is about 200 μm.

### Third Modified Example

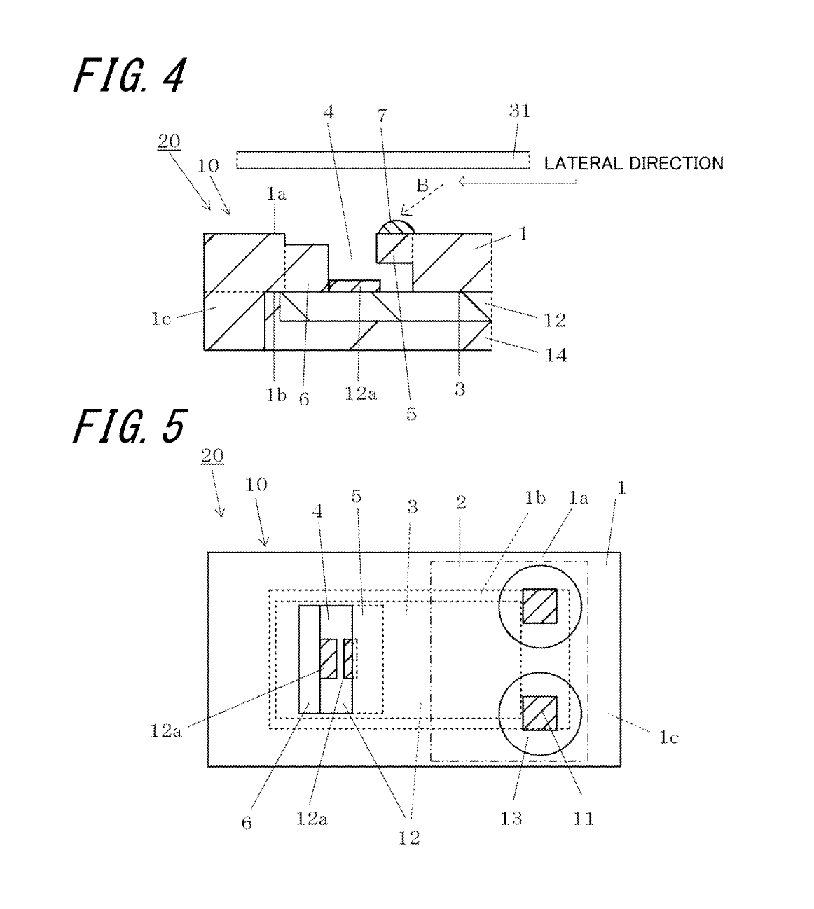

Moreover, as in the example shown in FIG. 4 for example, the sensor substrate 10 and the sensor device 20 of the embodiment may further comprises a projection 7 extending upwardly at a part of the upper surface 1a of the substrate 1 which part lies near the through hole 4 in the lateral direction.

The projection 7 is lower in height than the light-emitting element 11 mounted on the first mounting area 2. Since the height of the projection 7 is lower than the height of the light-emitting element 11, the possibility that the projection 7 will interfere with outward emission of light from the light-emitting element 11 is efficiently reduced. Moreover, the possibility of mechanical damage to the projection 7 is reduced.

By the projection 7, the possibility that undesired light having a large angle of incidence will enter the through hole 4 is reduced. Thus, in this case, in conjunction with the above-described effects of the protrusion within the through hole 4, the possibility that undesired light will enter the second mounting area 3 through the through hole 4 can be effectively reduced.

For example, the projection 7 may be formed of a material similar to that used for the substrate 1 by a method similar to that adopted for the formation of the substrate 1. For example, in the case where the projection 7 is formed of a ceramic material similar to that used for the substrate 1, the projection 7 can be formed in the following manner. Raw material powder similar to that used for forming the substrate 1 (aluminum oxide, etc.) is kneaded with an organic solvent to prepare a paste. After that, the paste is applied to a predetermined location on the ceramic green sheet which becomes the substrate 1, and, the paste and the ceramic green sheet which becomes the substrate 1 (laminated body) are co-fired. In this way, the projection 7 can be formed integrally with the substrate 1 comprising the first protrusion 5, the second protrusion 6, the frame portion 1c, etc.

In the case where the substrate 1 is formed of an organic resin material, with use of the above-described mold adapted to have a portion conforming to the shape of the projection 7, the organic resin material can be molded into the substrate 1 with an integral projection part. In this way, the substrate 1 having the projection 7 can be produced.

In addition, pigments or the like which is effective for interception of undesired light such as infrared rays by light absorbing or reflecting capability, may be added to the projection 7.

In the sensor substrate 10 and the sensor device 20 of the above-described embodiment, the substrate 1 and the protrusion may be integrally formed of the same ceramic material.

In this case, both the mechanical strength of the protrusion and the strength of connection of the protrusion to the substrate 1 can be effectively enhanced. Moreover, each of the first protrusion 5 and the second protrusion 6 exhibits relatively high mechanical strength in itself. Therefore, the possibility of mechanical damage to the substrate 1 including the first protrusion 5 and the second protrusion 6 is effectively reduced. Thus, this construction is effective also for improvement in the long-term reliability of the sensor substrate 10 and the sensor device 20.

Moreover, since the substrate 1, the first protrusion 5, and the second protrusion 6 can be integrally formed through one co-firing process, this is also advantageous from the viewpoint of productivity.

The sensor device 20 of the embodiment comprises: the sensor substrate 10 having any one of the above-described structures; the light-emitting element 11 mounted on the first mounting area 2; the light-transmitting sealing material 13 which covers the light-emitting element 11; and the light-receiving element 12 having the light-receiving portion 12a, the light-receiving element 12 being mounted on the second mounting area 3 so that the light-receiving portion 12a faces the opening of the through hole 4.

According to such a sensor device 20, since the sensor device comprises the sensor substrate 10 having the above-described structure, it is possible to effectively reduce the possibility of undesired light reception by the light-receiving element 12.

The light-emitting element 11 and the light-receiving element 12 are fixedly joined to the first mounting area 2 and the second mounting area 3, respectively, via, for example, a brazing material such as a low-melting-point brazing metal containing solder, or a joining material such as an adhesive or glass (not shown).

The light-emitting element 11 and the light-receiving element 12 may be electrically connected to an external electric circuit via, for example, a wiring conductor as described earlier. Electric power for light emission (photoelectric conversion) from the external electric circuit is supplied, via the wiring conductor, to the light-emitting element 11, and, the light-receiving element 12 transmits information about the detection of reflected light.

### Fourth Modified Example

FIG. 5 is a plan view showing another modified example of the sensor device 20 of the embodiment. In FIG. 5, such constituent components as are common to those shown in FIGs. 1A and 1B are identified with the same reference symbols.

In the sensor device 20 of this modified example, a plurality of light-emitting elements 11 are mounted on the first mounting area 2.

Since the plurality of light-emitting elements 11 are mounted on the first mounting area 2, it is possible to provide the sensor device 20 which easily and effectively detects the approach of a target object in a plurality of directions. In the example shown in FIG. 5, the plurality of light-emitting elements 11 are substantially equidistant from the through hole 4. Note that the plurality of light-emitting elements 11 may be arranged at different distances from the through hole 4.

### Fifth and Sixth Modified Examples

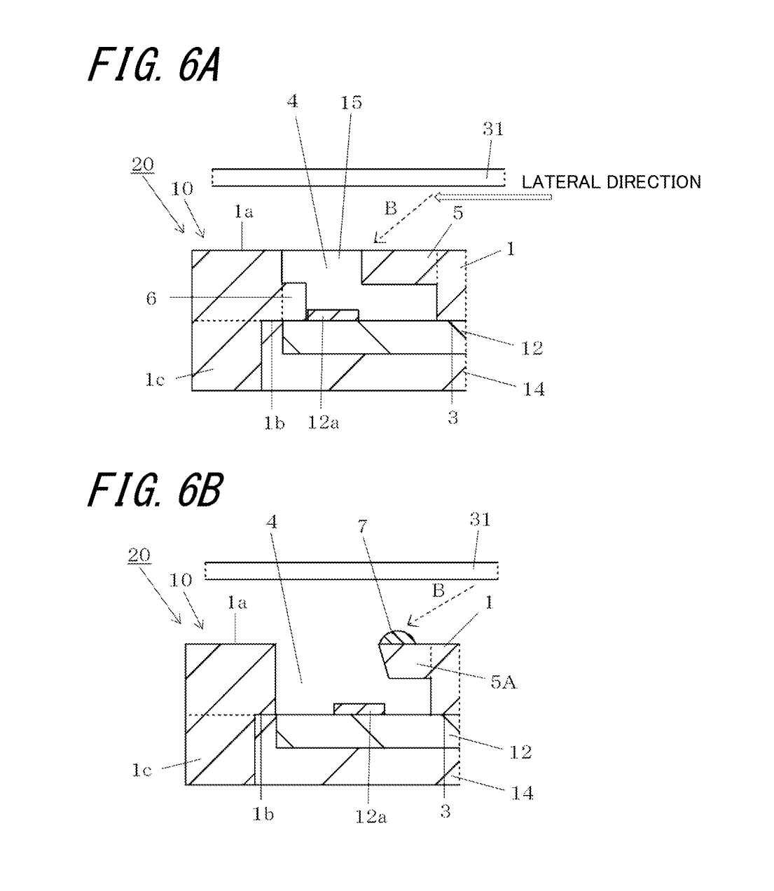

FIGS. 6A and 6B are each a sectional view showing the principal part of another modified example of the sensor substrate 10 and the sensor device 20 in accordance with the embodiment of the invention. In FIGS. 6A and 6B, such constituent components as are common to those shown in FIGS. 1A and 1B are identified with the same reference symbols.

In the example shown in FIG. 6A, the dimension of the first protrusion 5 is greater than the dimension of the second protrusion 6 in a lateral direction along a virtual straight line (not shown in FIG. 6A) extending from the first mounting area 2 to the through hole 4.

In this case, the first protrusion 5 disposed at the upper end of the through hole 4 on the first mounting area 2 side is elongated in the opposite direction away from the first mounting area 2. This leads to further increase in the angle of incidence of undesired light which tries to enter into the opening of the through hole 4 from the first mounting area 2. Hence, the possibility that undesired light will enter the through hole 4 is reduced by the first protrusion 5.

In this case, the protrusion which is thinner than the substrate 1 is located close to the outside of the construction. Therefore, for example, the sensor device 20 needs to be handled carefully to avoid mechanical damage such as chipping to the protrusion. From the standpoint of reducing the possibility of such a mechanical damage, the earlier described construction in which the second protrusion 6 has a relatively large lateral dimension is suitable for this purpose.

Moreover, in the example shown in FIG. 6A, a light-transmitting material 15 is disposed within the through hole 4. For example, the light-transmitting material 15 serves to protect the light-receiving portion 12a from an environment or the like inside the housing. Reflected light from a target object is allowed to reach the light-receiving portion 12a through the light-transmitting material 15, wherefore there arises no problem in the detection of reflected light by the light-receiving element 12.

The light-transmitting material 15 may be formed from a material similar to that used for the earlier described light-transmitting sealing material 13 by a method similar to that adopted for the formation of the light-transmitting sealing material 13. For example, as practiced in the example shown in FIG. 6A, the light-transmitting material 15 may be allowed to fill the through hole 4 thoroughly.

In the alternative, the light-transmitting material 15 may be disposed so that part thereof extends upwardly beyond the upper end of the through hole 4 (not shown). Moreover, the light-transmitting material 15 may have a filter function to cut light which is not subjected to detection, such as ultraviolet rays.

In the example shown in FIG. 6B, the inner surface of the through hole 4 is provided with one protrusion 5A. The one protrusion 5A is, as exemplified, located at the similar position to the earlier described first protrusion 5. Also in this case, the possibility that undesired light beam B will enter the through hole 4 is reduced by the one protrusion 5A.

Also in this case, by providing the protrusion 7, it is possible to enhance the effect of reducing the possibility that the undesired light beam B will enter the through hole 4.

Moreover, in the example shown in FIG. 6B, the side surface of the one protrusion 5A is formed as a slanted surface inclined outwardly from the upper end to the lower end thereof. This allows reflected light which has entered the through hole 4 at a low angle of incidence (not shown in FIG. 6B) to reach the second mounting area 3 (light-receiving element 12) through the through hole 4 readily, while effectively blocking the undesired light beam B at the upper surface part of the one protrusion 5A.

### Seventh Modified Example

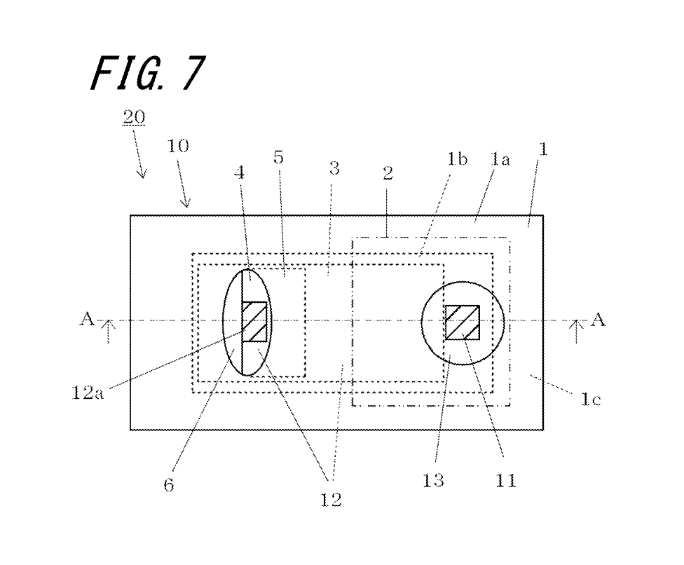

FIG. 7 is a plan view showing still another modified example of the sensor substrate 10 and the sensor device 20 in accordance with the embodiment of the invention. In the example shown in FIG. 7, the through hole 4 has an elliptical opening in plan view. From this, it follows that a front end (the end opposite from the end located toward the first mounting area 2) of the first protrusion 5 has an elliptically arcuate shape. The elliptical shape is oriented with a minor axis thereof aligned with the lateral direction along the line extending from the first mounting area 2 to the through hole 4. The midportion in the direction of a major axis of the elliptical shape defines a relatively large opening, and, the light-receiving portion 12a is located below this relatively large opening.

In this case, for example, when the light-receiving portion 12a of the light-receiving element 12 is smaller in size than the opening of the through hole 4 in plan view, the possibility of arrival of undesired light at the light-receiving portion 12a is effectively reduced. When the light-receiving portion 12a which is smaller than the opening of the through hole 4 in plan view is located at the center of the through hole 4 as seen in plan view, it is advantageous in the following point. That is, it is possible to reduce the entry of undesired light into the through hole 4 in a position other than the light-receiving portion 12a while sufficiently securing opening dimensions for the light-receiving portion 12a.

Accordingly, it is possible to provide the sensor device 20 in which the possibility of undesired light reception by the light-receiving portion 12a is effectively reduced. In addition, it is possible to provide the sensor substrate 10 which facilitates manufacture of such a sensor device 20.

It should be understood that the invention is not limited to the embodiments and modified examples thereof as described heretofore, and that various changes are possible without departing from the scope of the invention. For example, the inner surface of the through hole 4 may be made greater in surface roughness (made rougher) than, for example, the upper surface 1a of the substrate 1. This makes it possible to enhance the strength of connection of the light-transmitting material 15 to the through hole 4, for example.

Moreover, an exposed surface of the wiring conductor may be covered with a plating layer composed of nickel, gold, etc. Besides, the frame portion 1c may be omitted from the construction (not shown). In the absence of the frame portion 1c, a spacer member (not shown) may be interposed between the lower surface 1b of the substrate 1 and an external electric circuit such as a motherboard to leave a space between the substrate 1 and the external electric circuit.

### REFERENCE SIGNS LIST

1: Substrate

1a: Upper surface

1b: Lower surface

1c: Frame portion

2: First mounting area

3: Second mounting area

4: Through hole

5: First protrusion

6: Second protrusion

7: Projection

10: Sensor substrate

11: Light-emitting element

12: Light-receiving element

12a: Light-receiving portion

13: Light-transmitting sealing material

14: Sealing material

15: Light-transmitting material

20: Sensor device

31: Part of electronic apparatus (glass plate)

A: Reflected light beam

B: Undesired light beam

L: Virtual straight line

1. A sensor substrate, comprising:
a substrate comprising an upper surface including a first mounting area on which a light-emitting element is mounted, and a lower surface including a second mounting area on which a light-receiving element is mounted,
the substrate being further located with a through hole therethrough extending from a portion of the upper surface which portion is adjacent to the first mounting area, to the second mounting area of the lower surface,
an inner surface of the through hole being located with at least one protrusion extending inwardly within the through hole.

2. The sensor substrate according to claim 1, wherein the inner surface of the through hole is located with a plurality of the protrusions, and
the plurality of the protrusions include a first protrusion disposed at an upper end of the through hole on a first mounting area side, and a second protrusion disposed at a lower end of the through hole on a side opposite to the first mounting area.

3. The sensor substrate according to claim 2, wherein a vertical dimension of the second protrusion is greater than a vertical dimension of the first protrusion.

4. The sensor substrate according to claim 2, wherein a dimension of the second protrusion is greater than a dimension of the first protrusion in a lateral direction along a virtual straight line extending from the first mounting area toward the through hole.

5. The sensor substrate according to claim 1, further comprising:
a projection extending upwardly at a part of the upper surface of the substrate which part lies near the through hole in a lateral direction along a virtual straight line extending from the first mounting area toward the through hole,
wherein a height of the projection is lower than a height of the light-emitting element to be mounted on the first mounting area.

6. The sensor substrate according to claim 1, wherein the substrate and the protrusion are integrally formed of a same ceramic material.

7. A sensor device, comprising:
a sensor substrate according to claim 1;
a light-emitting element mounted on the first mounting area;
a light-transmitting sealing material which covers the light-emitting element; and
a light-receiving element comprising a light-receiving portion and mounted on the second mounting area, the light-receiving portion facing an opening of the through hole.

8. The sensor device according to claim 7, wherein a plurality of the light-emitting elements are mounted on the first mounting area.
